(19) United States
(12) Patent Application Publication
(10) Pub. No.: US 2022/0027982 A1
(43) Pub. Date: Jan. 27, 2022

(54) SYSTEMS AND METHODS FOR PROCESSING IMAGES OF PERSONS

(71) Applicant: eStylar Corp., Weehawken, NJ (US)

(72) Inventors: Augusto Chesini, Buenos Aires (AR); Matias Gath, Buenos Aires (AR); Lucas Gath, Buenos Aires (AR); Daniel Salcedo, Weehawken, NJ (US)

(73) Assignee: eStylar Corp., Weehawken, NJ (US)

(21) Appl. No.: 17/386,125

(22) Filed: Jul. 27, 2021

Related U.S. Application Data
(60) Provisional application No. 63/056,928, filed on Jul. 27, 2020.

(51) Int. Cl. G06Q 30/06; G06T 7/62; G06T 7/73; G06T 7/174; G06F 30/25; G06N 3/02

(52) U.S. Cl. CPC G06Q 30/0643; G06T 7/62; G06T 7/75; G06T 7/174; G06Q 50/01; G06F 30/25; G06N 3/02; G06T 2207/30196; G06T 2207/20084; G06Q 30/0631

(57) ABSTRACT

An image processing method is disclosed. The method includes capturing a front image and a side image of a user; processing the images in parallel through a human person segmentation neural network module, a body part segmentation neural network module, and a pose detection neural network module; and processing the outputs from the modules through first and second Kalman filters to obtain the measurements of the user.

### FIELD OF THE INVENTION

Embodiments of the present invention generally relate to a system and method for image processing to accurately obtain measurements of a person's body through the use of artificial intelligence and computer vision.

### BACKGROUND

When products such as items of clothing are offered for sale by a retailer in a physical location, as opposed to a website, the retailer's employees typically assist a customer in the process of selecting outfits. The main benefit of purchasing clothing in a retail store is that customers can try different outfits of different sizes and just choose the outfits that fit best. By purchasing items of clothing in person, customers avoid the potential inconsistencies in the designation of clothing sizes among retailers. For example, it is generally known that a shirt with a size medium designation from a first retailer may not match the actual size of another shirt with a size medium designation offered by another retailer.

By purchasing ems of clothing on a retailer's Internet website, customers may purchase a garment of a size they believe will fit them only to find out that the garment does not fit them well once they receive the ordered product. Thus, the initial convenience of shopping remotely may actually result in the inconvenient situation where customers have to return an ordered item.

In light of the foregoing, there is a need in the art for a system and method that allows customers to personalize the virtual shopping experience through the system's acquired knowledge about the customers and personalizing the commercial offer, as well as the adaptation of the user's experience to their preferences and needs in order to obtain a better conversion from customers.

### SUMMARY

The following presents a simplified summary of the invention in order to provide a basic understanding of some aspects of the invention. This summary is not an extensive overview of the invention. Rather than specifically identifying key or critical elements of the invention or to delineate the scope of the invention, its purpose, inter alia, is to present some concepts of the invention in a simplified form as a prelude to the more detailed description that is presented later.

The present disclosure describes a technology platform that allows accurate measurement of a person's body through artificial intelligence and computer vision algorithms, which represents a substantial improvement to current solutions and can be used in current online stores as a means to obtain a more precise sizing.

The method disclosed herein may include a number of steps. In one implementation, a first step includes the taking of a person's measurement. By taking photographs of the person., the measurement of all the proportions of the body is carried out or computed in order to have a precise digital and logical representation of the body that allows an adequate selection of garments.

In one implementation, a second step includes offering shopping recommendations to the person whose measurements were taken in the first step. Once the system acquires knowledge about the shape of the person's body, the type of clothing used or clothing preferences, and the user's behavior in the purchases made, the platform can automatically make recommendations for appropriate clothing or sets and new additions to the user's collection.

In one implementation, a third step includes adaptation of user's shopping experience. Each user requires specific attention to his or her purchasing or shopping process, which is why is the system may adapt to comport with user's preferences such that users can get the attention to detail, speed or options appropriate for each person.

The following description and the drawings set forth in detail certain illustrative aspects of the invention. These aspects are indicative, however, of but a few of the various ways in which the principles of the invention may be employed and the present invention is intended to include all such aspects and their equivalents. Other advantages and novel features of the invention will become apparent from the following description of the invention when considered in conjunction with the drawings.

### BRIEF DESCRIPTION OF THE DRAWINGS

The drawings, in which like numerals represent similar parts, illustrate generally, by way of example, but not by way of limitation, various embodiments discussed in the present document.

FIG. 1 illustrates an image capture process in accordance with one embodiment.

FIG. 2 illustrates a flowchart describing image processing to calculate measurements of a user's body in accordance with one embodiment.

FIG. 3 illustrates a flowchart describing image processing to calculate measurements of a user's body in accordance with one embodiment.

FIGS. 4-7 illustrate a total of twenty eight body measurements that are calculated by processes disclosed in accordance with one embodiment.

FIG. 8 illustrates a method for selection of items to purchase in accordance with one embodiment.

FIG. 9 illustrates several high and low resolution body key points calculated after scanning of a body image in accordance with one embodiment.

### DETAILED DESCRIPTION

The foregoing summary, as well as the following detailed description of certain embodiments of the subject matter set forth herein, will be better understood when read in conjunction with the drawings. In the following detailed description, reference is made to the accompanying drawings which form a part hereof, and in which are shown by way of illustration specific embodiments in which the subject matter disclosed herein may be practiced. These embodiments, which are also referred to herein as “examples,” are described in sufficient detail to enable those skilled in the art to practice the subject matter disclosed herein. It is to be understood that the embodiments may be combined or that other embodiments may be utilized, and that variations may be made without departing from the scope of the subject matter disclosed herein. Further more, references to “one embodiment” are not intended to be interpreted as excluding the existence of additional embodiments that also incorporate the recited features. The following detailed description is, therefore, not to be taken in a limiting sense, and the scope of the subject matter disclosed herein is defined by the appended claims and their equivalents.

The description below details the operation of each of the subsystems that are part of the process that may be implemented by the system of the present invention.

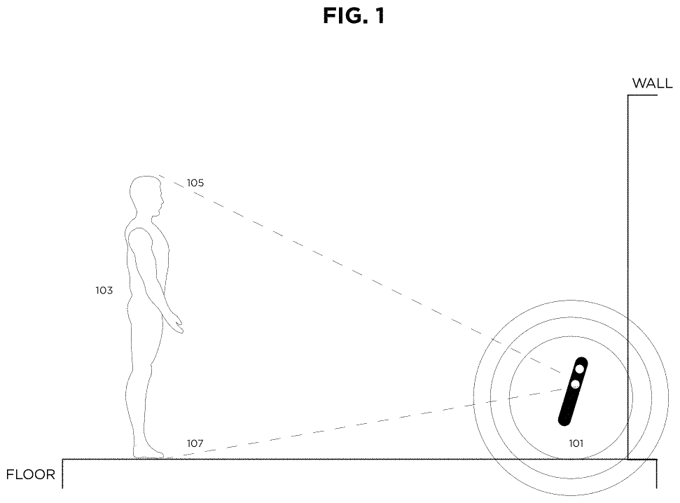

FIG. 1 illustrates an image capture process to calculate measurements of a user's body in accordance with one embodiment. In order to obtain the measurements of a person's body, the person 103 is photographed. The process may begin by taking two pictures of the person using that person's mobile phone 101 or tablet, for example. The person may position the phone or tablet against a wall at an angle as an app installed on the phone or tablet captures images of the front and from the side of the person 103.

The user 103 should be able to see his or her entire body (top 105 to bottom 107) captured by the imaging process performed by the mobile app. In one implementation, if the user 103 desires to use a desktop computer, a marker code may allow the person to run the imaging process from a mobile phone or tablet, and once the imaging process and analysis has been completed by the system, the app will notify the user that the imaging analysis has been uploaded to a website or desktop computer and that the user can then access the website or desktop to complete the shopping experience from the website or desktop.

The system performs image processing as the pictures are taken. The image processing may be performed by the mobile app, a desktop, or by a server in the cloud. The measurement estimation pipeline may require two inputs: the user height and weight. Firstly, with the user camera feed, the system may use a neural network to estimate the user position (in one implementation the system may use posenet with a multiplier of 0.5 to improve speed). If the user is in the correct position (for example centered, with the arms and legs slightly extended and open) the system processes an array of photos of the user's front profile. Then, when the user turns to his or her side and is in the correct side position the system processes an array of photos of his or her side.

Having these two arrays, the system then preprocess all of the photos with a human person segmentation neural network, which in one implementation may be an improved and web based version of deeplab. The system then downloads a parametric 3D model of the human body that has 38 bones and 6 morph targets. Having the model and the user's weight and height, the system then estimates the 3D model morph targets with a multivariate gaussian distribution (with its respective covariance matrix) which outputs the users estimated waist, hips, bust and inseam, and the system modified the 3D model accordingly.

The system then proceeds to use a Particle Swarm Optimization (PSO) algorithm to match the segmented human photo and the 3D model 2D projection, varying the camera external parameters (position and rotation) and the model morph targets. This process calculates the volumetric representation of the human body with the shadow it projects, making this approach unique both in speed and accuracy.

Once the system achieves sufficient precision or once the system has achieved the maximum number of iterations programmed into the algorithm, the program may stop. The system then uses geodesic measurements to measure the 3D model circumferences and a Kalman filter to fine-tune the results. Once the user's real measures are obtained, the system may use that user data alongside the estimated measures to improve the Kalman filtering process.

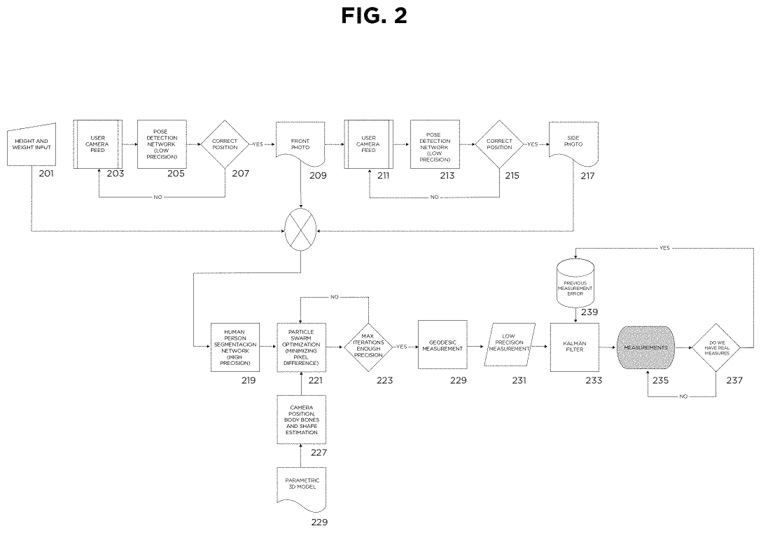

FIG. 2 illustrates a flowchart describing image processing to calculate measurements of a user's body in accordance with one embodiment. In step 201 the user's height and weight is input. In step 203 the camera of a mobile phone or tablet captures the user's front image and in step 205 an app in the mobile phone detects the pose of the user by using a low precision pose detection algorithm. Step 207 determines whether the user's pose is correct for further processing and if is not, then steps 203 and 205 are repeated until the correct user position (for further processing) is detected.

If the correct user position is detected then an image of the front of the user is stored at step 209 and the camera captures an image of the side of the user at step 211. In step 213 an app in the mobile phone detects the side pose of the user by using a low precision pose detection algorithm. Step 215 determines whether the user's side pose is correct for further processing and if is not, then steps 211 and 213 are repeated until the correct user side position (for further processing) is detected. In step 217 the user's side pose is stored. The user images (front 209 and side 217) together with the user's weight and height information are fed to a step 219 which conducts a human person segmentation neural network process (high precision).

In step 225 a parametric 3D model generated and then fed to a module 227 that processes 3D model and estimates the camera position, user's body bone position and user's shape estimation. The outputs from the segmentation step 219 and estimation step 227 are fed to a module 221 that performs particle swarm optimization (minimizing pixel difference) with the step 221 conducting iterations until a maximum number of iterations to meet a threshold desired precision (step 223) is achieved. In step 229 geodesic measurements are calculated for the user based on the data output by step 223, which is then used to calculate low precision user measurements in step 229.

In step 233 a feedback or adaptive Kalman filtering process is applied until the proper measurements (output at step 235) are produced. The filtering process 233 goes through several iterations based on a threshold set for establishing real measurements 237 and a measurement error signal 239 which is fed back to the filtering step 233.

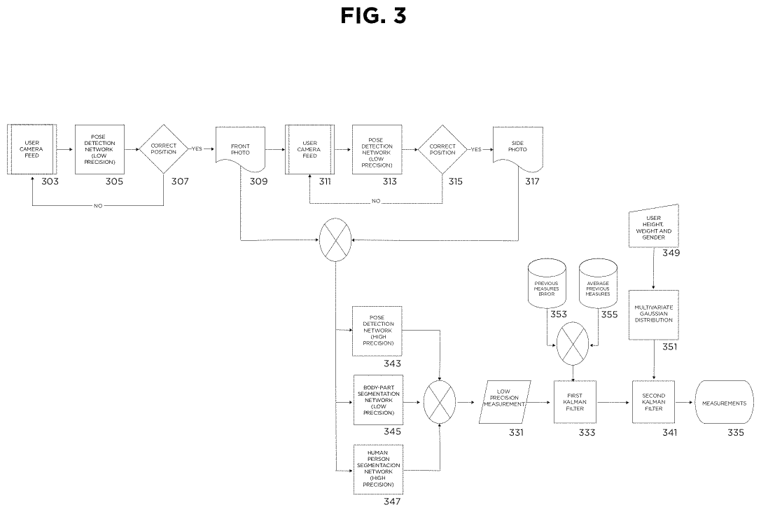

FIG. 3 illustrates a flowchart describing image processing to calculate measurements of a user's body in accordance with one embodiment. In step 303 the camera of a mobile phone or tablet captures the user's front image and in step 305 an app in the mobile phone or backend computer detects the front pose of the user by using a low precision pose detection algorithm (neural network). Step 307 determines whether the user's pose is correct for further processing and if is not, then steps 303 and 305 are repeated until the correct user position (for further processing) is detected.

If the correct user position is detected then an image of the front of the user is stored at step 309 and the camera captures an image of the side of the user at step 311. In step 313 an app in the mobile phone or backend computer detects the side pose of the user by using a low precision pose detection algorithm. Step 315 determines whether the user's side pose is correct for further processing and if is not, then steps 311 and 313 are repeated until the correct user side pose (for further processing) is detected. In step 317 the user's side pose is stored. The user images (front 309 and side 317) are fed to steps 343 (pose detection network—high precision), 345(body-part segmentation network—low precision), and 347 (human person segmentation network—high precision).

The outputs of modules or steps 343, 345 and 347 are fed to a module 331 that calculates low precision measurements corresponding to the user. The output from step 331 is fed to a first Kalman filter module 333 to produce a filtered signal based on the low precision measurements, a previous measurements error signal 353 and an average previous measurement 355.

In step 349 the height, weight and gender of the user is entered and a multivariate Gaussian distribution calculation 351 is applied to the output from step 349. The output from the first Kalman filtering process 333 and the Gaussian distribution calculation 351 are fed to a second Kalman filtering step 341, which produces the desired user measurements 335.

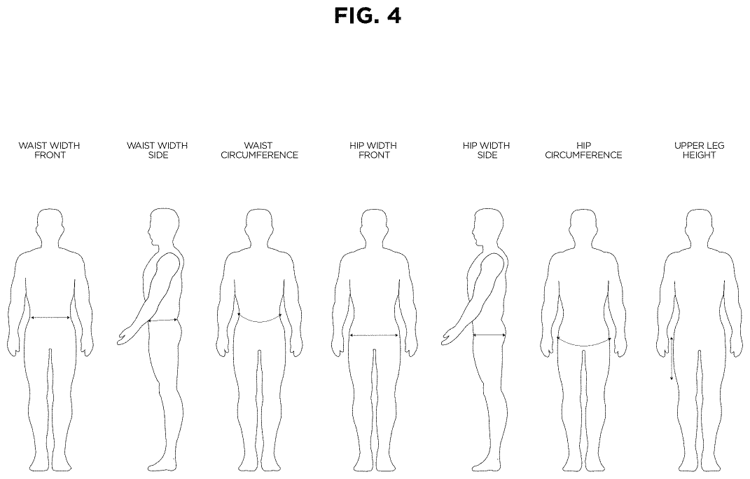

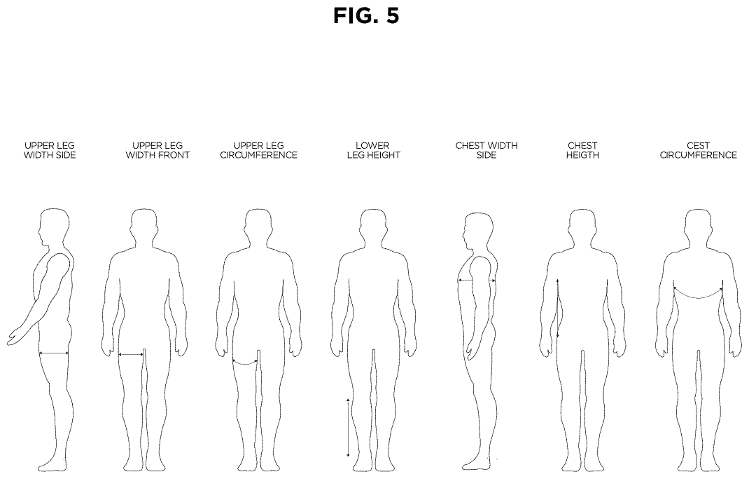

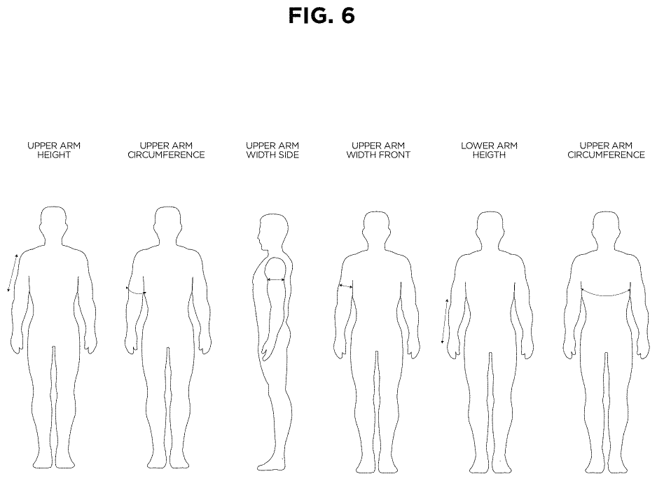

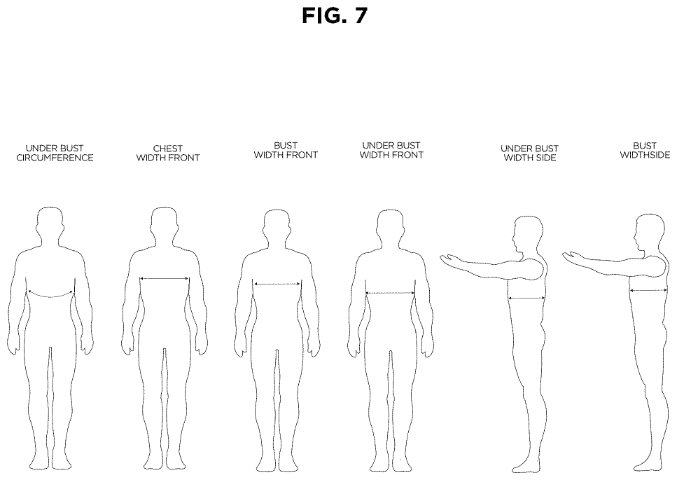

Once the user's real measures are obtained, the system applies an algorithm to check 26 different measurements of the body. The different up and lower body analysis allows for a precise fit when cross-checked with the sizing charts available from the different brands. The exemplary 26 measurements are illustrated in FIGS. 4-7.

After the analysis is completed, the system saves the numbers (measurements) and determined body shape in accordance with one implementation. For each measurement, and for some others that are calculated based on the physical ones, the platform records the values, and no image is required to be sent to the server as the algorithm runs on the client side in accordance with one implementation.

In another aspect of the invention, the system may make shopping recommendations to the user. For example, the system may obtain different sources of information as input to the process by requesting access to those sources to obtain additional user data and improve recommendations. Upon user granting access to social network account, the system may access user photos to learn about the user's environment and preferred styles. The system may also generate surveys that inquire about clothing preferences and celebrity styles for users to fill out. Based on these additional sources of information and the user's real measurements, the body shape can be determined and the body shape information may be used to categorize garments to be recommended for purchase.

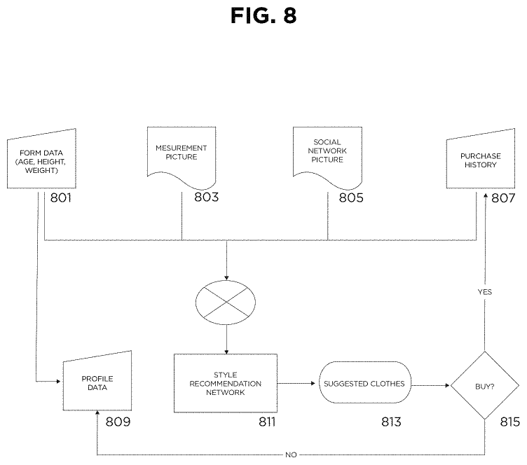

With the information collected, the system may automatically analyze the person's past purchases, size, body shape, environment and behaviors in order to suggest garments that match the person's taste. The system may collect all the available data and through the use of machine learning algorithms, refines the profiles and infers possible style matches and desirable purchases to offer to the customer. In one implementation, the garment suggestion process can be implemented as illustrated in FIG. 8. In step 811 a style recommendation neural network processes form data (801—user's age, height, weight, etc.), a user measurement picture 803, social media pictures for the user 805 and purchase history data for the user 807. The style recommendation step produces a listing of suggested garments 813 for the user to purchase. In step 315 the user's decision whether to purchase one or more of the suggested garments is tracked. Data corresponding to the garments selected by the user for purchase will be recorded in module 807. Conversely, data corresponding to the garments not selected by the user for purchase will be recorded in module 809, which may be defined as the user's profile in the disclosed system.

Through the use of those machine learning algorithms the system may constantly learn about the customer and may provide tips on new clothes, combinations, colors, fabrics and event recommendations. In this manner, the system acts as a personal image assessor, providing messages displayed through a user's mobile app or through emails when the customer seeks advice.

In yet another aspect, the system may allow the user to follow different shopping paths or options, with modular steps designed to provide as little or provide as much detail as the customer desires to make the shopping experience more comfortable. The knowledge base generated by the system and the user profile information may be used to create different layouts and front end visuals for each customer. Based on user behavior, past purchases, and customer profile, the platform may present different buying steps, screens, details, garments and options in order to adapt the experience for that particular customer to the criteria stated on the continuous analysis algorithms created from the collected data ranging from a single step purchase to an in depth process that provides the user complete control over all the details and options to make a purchase from the platform. Both automatic and question based feedback is constantly compiled to feed the platform and to adapt the criteria further as the user continues to use the system.

The following additional features may be implemented in the scanning methodology in accordance with different embodiments of the invention:
a. Determination of several high and low resolution body key points
b. Body segmentation by application of neural network technology
c. Kalman filters trained with thousands of persons or subjects for measurement cleaning
d. Neural network for measurement approximation based on statistical data of thousands of persons or subjects
e. Particle swarm optimization algorithm for improving measurements
f. Computer vision techniques for finding camera and positioning parameters
g. 3D body reconstruction based on morph targets
h. Body type statistical analysis and numerical integration methods
i. Multidimensional gaussian distribution integration for matching users with clothes based on size guides, elasticity of the clothes, preferred fit and body type
j. Development of an algorithm for finding user match in an O(log(n)) time complexity

The following additional features may be implemented for determining product similarity:
a. Neural network for finding 1550 key components in images
b. Multidimensional vectoral space for measuring similarity between garments in an Euclidean space

The following additional features may be implemented to produce or output a product recommendation:
a. Multi agent recommendation engine based on individual and collective user interactions, user measurements, user clustering and user similarity, that learns over time
b. Generation of a unique set of products for each user, managing millions of database entries

The following additional features may be used to implement user clustering and similarity:
a. Vectorial space where system manages all system users and products
b. K-medioids algorithm for clustering users and products
c. K nearest neighbors algorithm for finding similar users

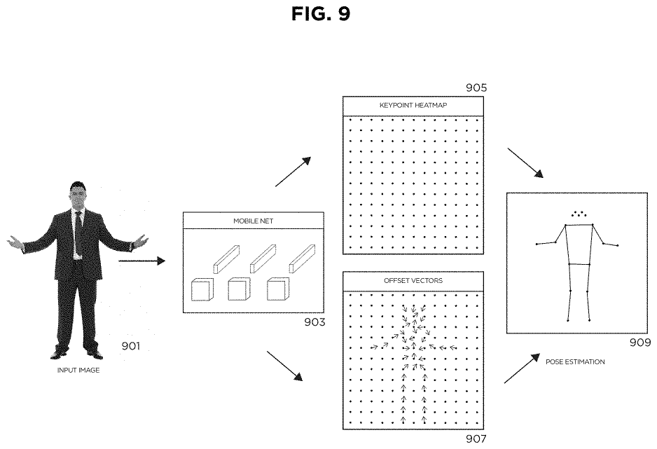

FIG. 9 illustrates several high and low resolution body key points calculated after scanning of a body image in accordance with one embodiment. In step 901 an image of the user is captured. In step 903 a pose estimator algorithm is applied to generate a key point heatmap 905 and offset vectors 907. In step 909 the pose estimation is output.

The various embodiments and/or components, for example, the modules, elements, or components and controllers therein, also may be implemented as part of one or more computers or processors or they may be implemented as software modules or components. The computer or processor may include a computing device, an input device, a display unit and an interface, for example, for accessing the Internet. The computer or processor may include a microprocessor. The microprocessor may be connected to a communication bus. The computer or processor may also include a memory. The memory may include Random Access Memory (RAM) and Read Only Memory (ROM). The computer or processor further may include a storage device, which may be a hard disk drive or a removable storage drive such as an optical disk drive, solid state disk drive (e.g., flash RAM), and the like. The storage device may also be other similar means for loading computer programs or other instructions into the computer or processor. Also, the term “computer” or “module” may include any processor-based or microprocessor-based system including systems using microcontrollers, reduced instruction set computers (RISC), application specific integrated circuits (ASICs), field-programmable gate arrays (FPGAs), graphical processing units (GPUs), logic circuits, and any other circuit or processor capable of executing the functions described herein. The above examples are exemplary only, and are thus not intended to limit in any way the definition and/or meaning of the term “computer.”

The computer or processor executes a set of instructions that are stored in one or more storage elements, in order to process input data. The storage elements may also store data or other information as desired or needed. The storage element may be in the form of an information source or a physical memory element within a processing machine.

The set of instructions may include various commands that instruct the computer or processor as a processing machine to perform specific operations such as the methods and processes of the various embodiments of the invention. The set of instructions may be in the form of a software program, which may form part of a tangible, non-transitory computer-readable medium or media. The software may be in various forms such as system software or application software. Further, the software may be in the form of a collection of separate programs or modules, a program module within a larger program or a portion of a program module. The software also may include modular programming in the form of object-oriented programming. The processing of input data by the processing machine may be in response to operator commands, or in response to results of previous processing, or in response to a request made by another processing machine.

As used herein, the terms “software”, “firmware” and “algorithm” are interchangeable, and include any computer program stored in memory for execution by a computer, including RAM memory, ROM memory, EPROM memory, EEPROM memory, and non-volatile RAM (NVRAM) memory. The above memory types are exemplary only, and are thus not limiting as to the types of memory usable for storage of a computer program. The term “module” may also refer to a software module that implements one or more steps of the processes described herein.

As used herein, an element or step recited in the singular and proceeded with the word “a” or “an” should be understood as not excluding plural of said elements or steps, unless such exclusion is explicitly stated. Moreover, unless explicitly stated to the contrary, embodiments “comprising” or “having” an element or a plurality of elements having a particular property may include additional such elements not having that property. In the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects. Further, the limitations of the following claims are not written in means—plus-function format and are not intended to be interpreted based on 35 U.S.C. 112(f), unless and until such claim limitations expressly use the phrase “means for” followed by a statement of function void of further structure.

1. An image processing method comprising:
capturing a front image and a side image of a user;
processing said images through a human person segmentation neural network module;
performing particle swarm optimization on the images processed through the human person segmentation neural network module; and
processing the particle swarm optimized images through a Kalman filtering process to obtain measurements of the user.

2. An image processing method comprising:
capturing a front image and a side image of a user;
processing said images in parallel through a human person segmentation neural network module, a body part segmentation neural network module, and a pose detection neural network module;
and processing the outputs from said modules through first and second Kalman filters to obtain the measurements of the user.

3. A method for suggesting garments for purchase to a user comprising:
receiving the user's age, height and weight information;
receiving the images of the user, including social media images;
processing purchase history data corresponding to the user, the user's age, height and weight information, and the images of the user through a style recommendation neural network module;
displaying garments to the user based on results generated by the style recommendation neural network module; and
recording purchase decisions by the user based on purchased garments displayed to the user.
